(19) United States
(12) Patent Application Publication
(10) Pub. No.: US 2025/0370706 A1
(43) Pub. Date: Dec. 4, 2025

(54) Sound Volume Setting Method, Sound Volume Setting Terminal, Earphones, and Sound Volume Setting System

(71) Applicant: Yamaha Corporation, Hamamatsu-shi (JP)

(72) Inventor: Yusuke KONAGAI, Hamamatsu (JP)

(21) Appl. No.: 19/306,543

(22) Filed: Aug. 21, 2025

Related U.S. Application Data
(63) Continuation of application No. PCT/JP2024/002395, filed on Jan. 26, 2024.

(30) Foreign Application Priority Data
Feb. 22, 2023 (JP) 2023-026070

(51) Int. Cl. G06F 3/16; H04R 1/10

(52) U.S. Cl. CPC G06F 3/165; G06F 3/162; H04R 1/1041; H04R 2420/07; H04R 2430/01

(57) ABSTRACT

A sound volume setting method includes receiving a correction instruction to correct a sound volume change characteristic for a sound volume change operation. The sound volume setting method also includes setting a reference value to a sound volume that is used at a time when the correction instruction is received, and generating a corrected sound volume change characteristic by correcting the sound volume change characteristic based on the reference value. The sound volume setting method also includes transmitting the corrected sound volume change characteristic.

### CROSS-REFERENCE TO RELATED APPLICATIONS

The present application is a continuation application of International Application No. PCT/JP2024/002395, filed Jan. 26, 2024, which claims priority to Japanese Patent Application No. 2023-026070, filed Feb. 22, 2023. The contents of these applications are incorporated herein by reference in their entirety.

### BACKGROUND

The present disclosure relates to a setting sound volume method, a sound volume setting terminal, earphones, and a sound volume setting system.

In related art, to make a call in a noisy environment, there is a sound volume adjustment device that allows fine adjustment of the sound volume (JP 2005-347878 A, for example). The sound volume adjustment device described in JP 2005-347878 A selects one of a plurality of prestored sound volume adjustment patterns in accordance with a user's operation, and sets sound volume based on the selected pattern.

There is also an audio device that uses a sound volume curve showing the relationship between the step number and the sound volume and moves a region of a large amount of operation in accordance with a user's operation, the region of a large amount of operation being a region where a change in sound volume that corresponds to the step number is smaller than the change in the other region (JP 2005-252725 A, for example).

The sound volume adjustment device described in JP 2005-347878 A requires selecting a prestored sound volume adjustment pattern. The audio device described in JP 2005-252725 A requires determining a position to which the region of a large amount of operation is moved. As described above, in the related-art devices for setting (adjusting) the sound volume, the user needs to manually select or move the region where the sound volume change characteristic is corrected in accordance with a sound volume change operation. There is no point in correcting the sound volume change characteristic in accordance with a sound volume change operation in a sound volume region that is rarely used by the user.

An object of the present disclosure is to provide a sound volume setting method that readily allows correction of a sound volume change characteristic in response to a sound volume change operation at a sound volume that is frequently used by a user.

### SUMMARY

One aspect is a sound volume setting method that includes receiving a correction instruction to correct a sound volume change characteristic for a sound volume change operation. The sound volume setting method also includes setting a reference value to a sound volume that is used at a time when the correction instruction is received, and generating a corrected sound volume change characteristic by correcting the sound volume change characteristic based on the reference value. The sound volume setting method al so includes transmitting the corrected sound volume change characteristic.

Another aspect is a sound volume setting terminal that includes a correction instruction acceptor, a change characteristic generator, and a transmitter. The correction instruction acceptor is configured to receive a correction instruction to correct a sound volume change characteristic for a sound volume change operation. The change characteristic generator is configured to set a reference value to a sound volume that is used at a time when the correction instruction is received, and generate to a corrected sound volume change characteristic by correcting the sound volume change characteristic based on the reference value. The transmitter is configured to transmit the corrected sound volume change characteristic to another terminal.

Another aspect is a sound volume setting system that includes the above-described sound volume setting terminal and earphones. The earphones includes a sound signal obtainer, a sound volume adjustor, and an outputter. The sound signal obtainer is configured to obtain a sound signal. The sound volume adjustor is configured to adjust a sound volume of the sound signal. The outputter is configured to output the sound signal. The sound volume setting terminal further includes a transmitter configured to transmit the generated corrected sound volume change characteristic to the earphones. The sound volume adjustor is configured to adjust the sound volume of the sound signal based on the corrected sound volume change characteristic. The outputter is configured to output the sound signal at sound volume based on the corrected sound volume change characteristic.

Another aspect is earphones each including a sound signal obtainer, a storage, a sound volume adjustor, and an outputter. The sound signal obtainer is configured to obtain a sound signal. The storage is configured to store a corrected sound volume change characteristic received from a portable terminal. The sound volume adjustor is configured to adjust the sound signal to have a sound volume based on the corrected sound volume change characteristic. The outputter is configured to output the sound signal at the adjusted sound volume.

A more complete appreciation of the present disclosure and many of the attendant advantages thereof will be readily obtained as the same becomes better understood by reference to the following detailed description when considered in connection with the following figures.

### BRIEF DESCRIPTION OF THE DRAWINGS

FIG. 1 is a block diagram showing an example of the configuration of a sound volume setting system;

FIG. 2 is a descriptive diagram showing a first sound volume curve;

FIG. 3 is a block diagram showing an example of the configuration of a portable terminal;

FIG. 4 is a descriptive diagram showing an example of an application program initial screen displayed on a display of the portable terminal;

FIG. 5 is a descriptive diagram showing an application program screen displayed on the display of the portable terminal when a Display dBA button is operated;

FIG. 6 is a descriptive diagram showing an application program screen displayed on the display of the portable terminal when a GO button is operated;

FIG. 7 is a descriptive diagram showing a second sound volume curve and a third sound volume curve;

FIG. 8 is a table showing an example of the sound volume corresponding to VOLn (operation value);

FIG. 9 is a flowchart showing an example of the operation of the portable terminal;

FIG. 10 is a block diagram showing an example of the configuration of earphones;

FIG. 11 is a descriptive diagram showing an example of a fourth sound volume curve in Variation 1;

FIG. 12 is a descriptive diagram showing an example of a fifth sound volume curve in Variation 2;

FIG. 13 is a descriptive diagram showing an example of a sixth sound volume curve in Variation 3; and

FIG. 14 is a descriptive diagram showing an example of a seventh sound volume curve in Variation 4.

### DETAILED DESCRIPTION

The present specification is applicable to a setting sound volume method, a sound volume setting terminal, earphones, and a sound volume setting system.

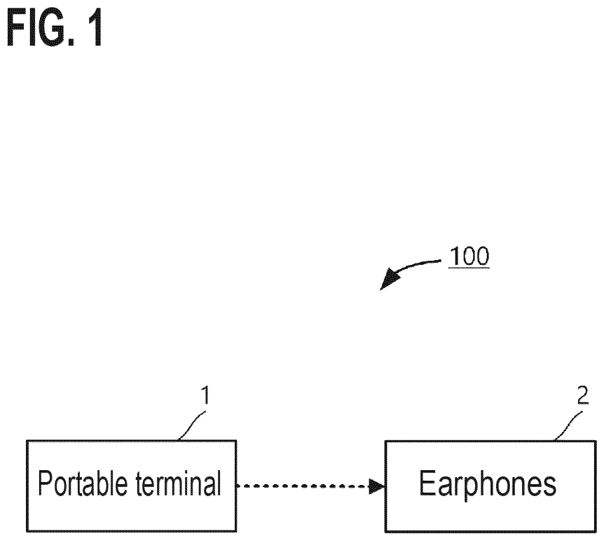

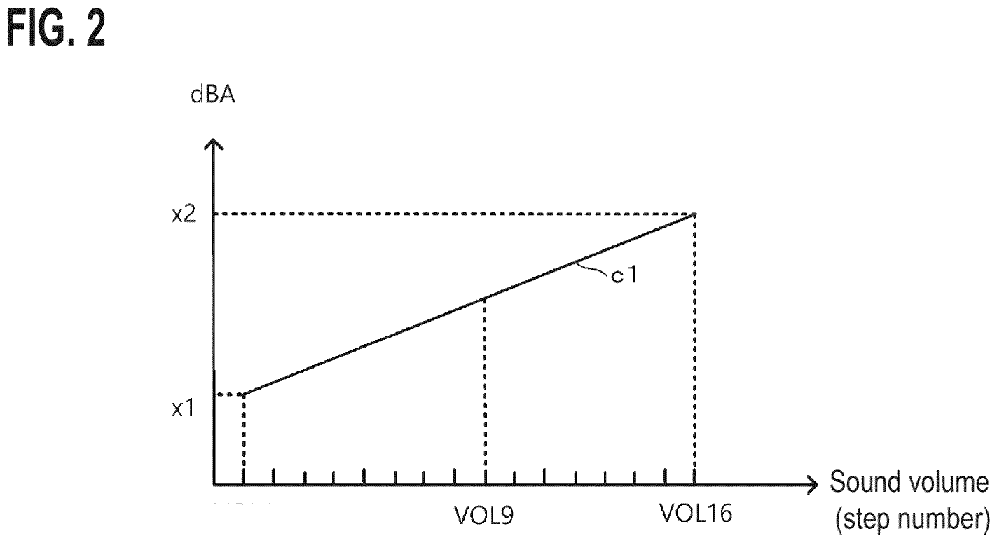

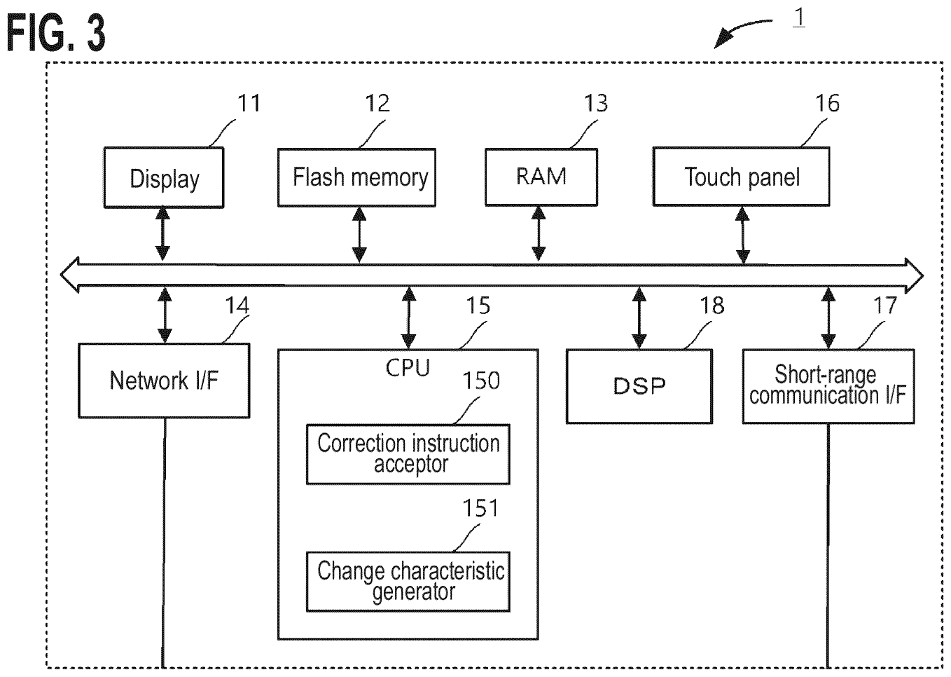

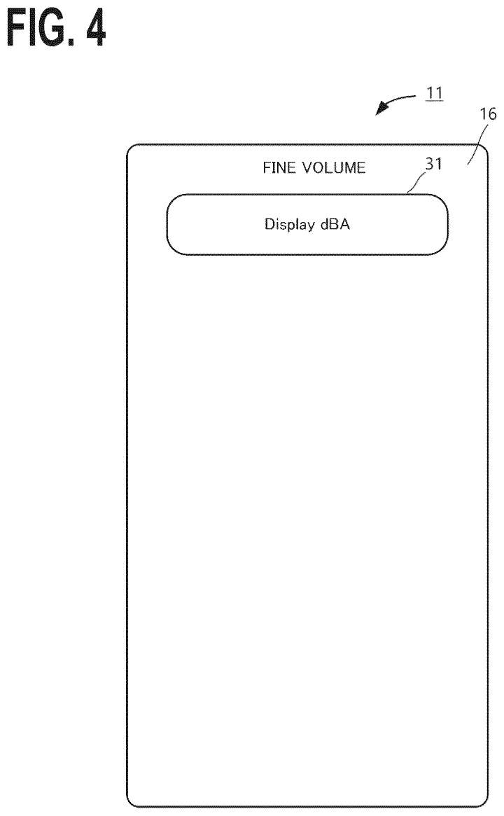

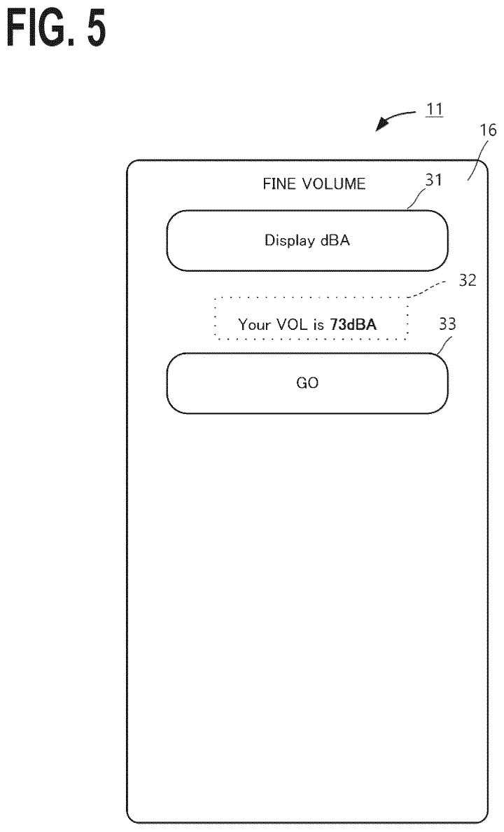

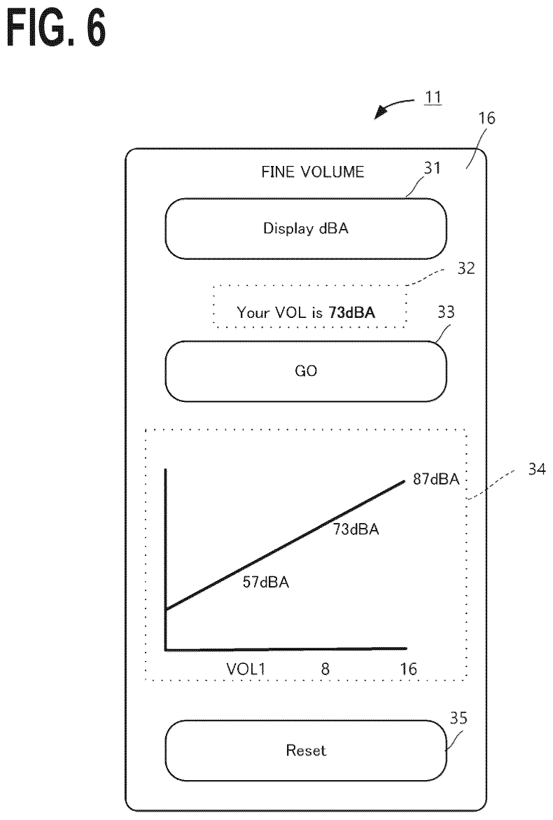

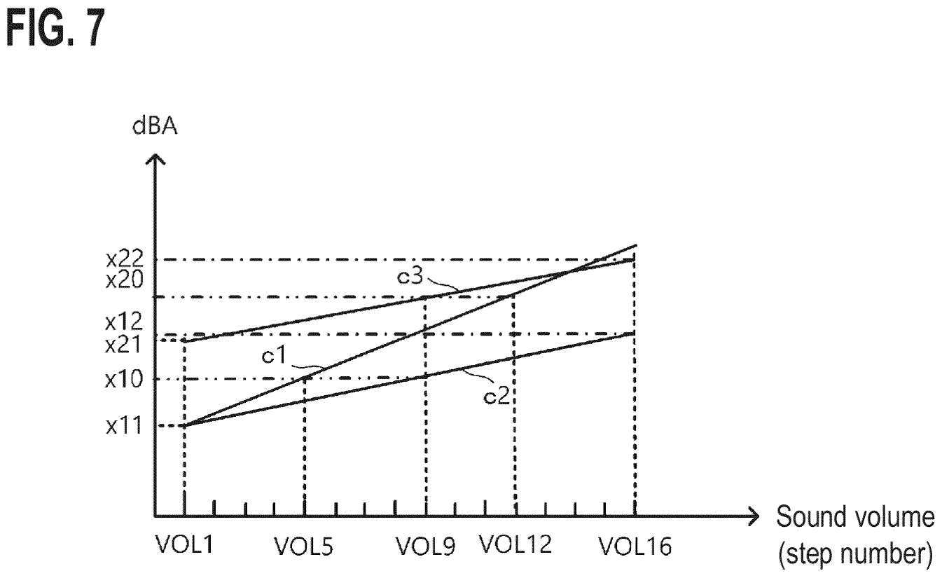

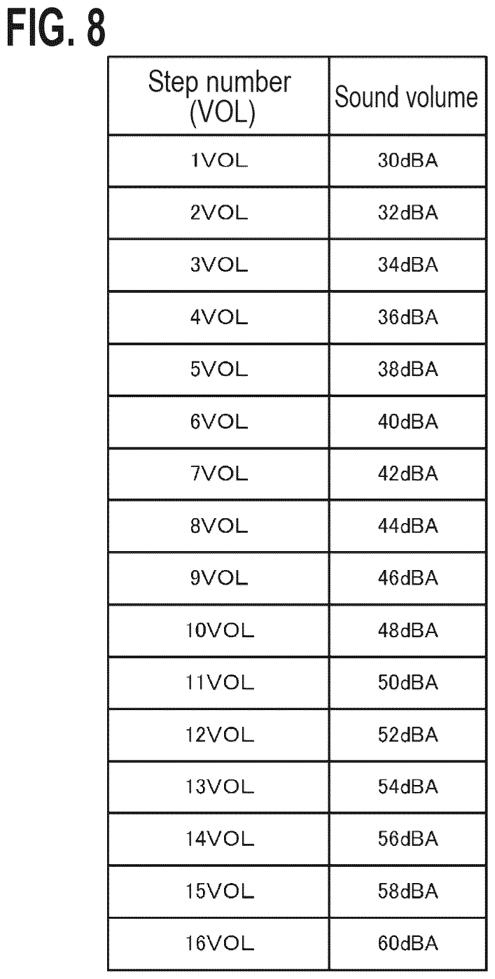

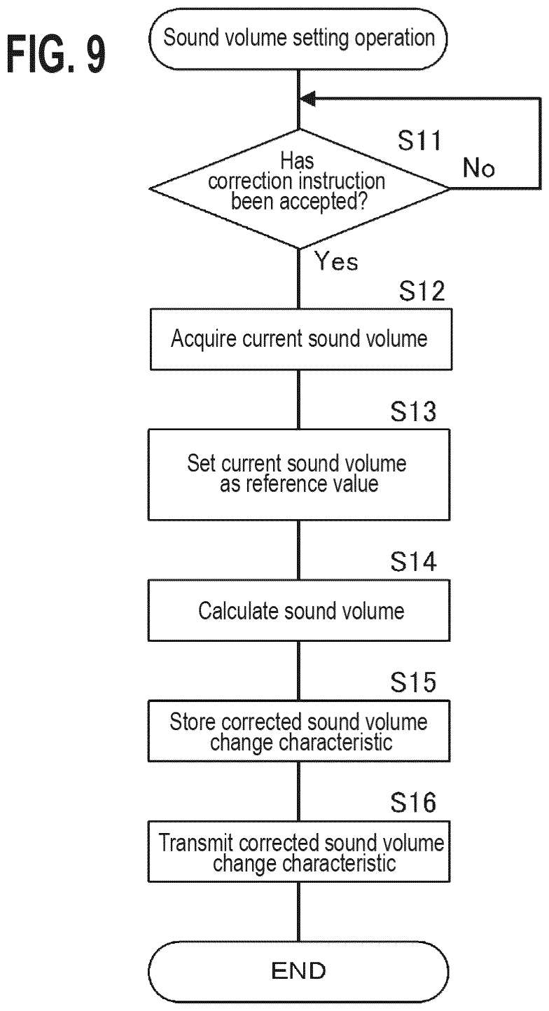

A sound volume setting system according to an embodiment of the present disclosure will be described with reference to FIGS. 1-9. FIG. 1 is a block diagram showing an example of the configuration of a sound volume setting system 100. FIG. 2 is a reference diagram showing a first sound volume curve c1. FIG. 3 is a block diagram showing an example of the configuration of a portable terminal 1. FIG. 4 is a descriptive diagram showing an example of an application program screen displayed on a display 11 of the portable terminal 1. FIG. 5 is a descriptive diagram showing an application program screen displayed on the display 11 of the portable terminal 1 when a Display dBA31 button is operated. FIG. 6 is a descriptive diagram showing an application program screen displayed on the display 11 of the portable terminal 1 when a GO button 33 is operated. FIG. 7 is a descriptive diagram showing a second sound volume curve c2 and a third sound volume curve c3 after correction. FIG. 8 is a table showing an example of the sound volume corresponding to VOLn (operation value). FIG. 9 is a flowchart showing an example of the operation of the portable terminal 1.

The sound volume setting system 100 includes the portable terminal 1 and earphones 2, as shown in FIG. 1. The portable terminal 1 is, for example, a smartphone, a tablet computer, or a portable music player. In FIG. 1, the portable terminal 1 transmits various signals to the earphones 2 via wireless communication such as Bluetooth (registered trademark). The portable terminal 1 described in this example is an example of a sound volume setting terminal according to the present disclosure.

The sound volume setting system 100 adjusts the sound volume to a user's preference in accordance with the user's operation accepted by the portable terminal 1. The portable terminal 1 transmits to the earphones 2 a sound signal of a sound (music or voice, for example) selected by the user. The portable terminal 1 accepts a sound volume adjustment operation from the user.

The portable terminal 1 sets the sound volume corresponding to each of 16 steps from VOL1 to VOL16 based on the first sound volume curve c1 shown in FIG. 2. In the example shown in FIG. 2, the difference between a minimum sound volume x1 and a maximum sound volume x2 in the first sound volume curve c1 is set to about 60 dBA. In this case, the minimum sound volume x1 is, for example, 30 dBA. The maximum sound volume x2 is, for example, 90 dBA.

The sound volume preferred by users, however, varies from person to person. For example, some users prefer to listen to sounds at great sound volume, whereas other users prefer to listen to sounds at small sound volume (quiet sound). As described above, even when the difference between the minimum sound volume x1 and the maximum sound volume x2 is 60 dBA, a user who prefers to listen to music at great sound volume rarely uses a small sound volume range. A user who prefers to listen to music at small sound volume rarely uses a great sound volume range.

In the first sound volume curve c1, the difference between the minimum sound volume x1 and the maximum sound volume x2 (sound volume adjustment width) is set to 60 dBA. When the sound volume adjustment range of 60 dBA can be divided into 16 steps (VOL1 to VOL16) for adjustment, the sound volume changes by 4 dBA per VOL. That is, the amount of change (slope) of the first sound volume curve c1 is 4 dBA/VOL. In the first sound volume curve c1, a change of just 1 VOL causes a difference in sound volume of 4 dBA, so that when the user attempts to adjust the sound volume, the sound volume may suddenly become greater or smaller. As described above, when the amount of change is set to 4 dBA/VOL, it is difficult for the user to make fine sound volume adjustment. The sound volume adjustment width described in this example is the amount of change in sound volume in the present disclosure.

In view of the background described above, the portable terminal 1 in the present embodiment generates a corrected sound volume change characteristic by correcting a sound volume change characteristic in accordance with a sound volume change operation in a sound volume region preferred by each user. The corrected sound volume change characteristic described in the description is based on a sound volume curve in which the sound volume corresponds to each of VOL1 to VOL16 (16 steps) in the sound volume range preferred by the user.

For example, the portable terminal 1 changes the amount of change per VOL from 4 dBA to 2 dBA. When the amount of change is changed, the sound volume adjustment width is also changed. The portable terminal 1 generates a sound volume curve based on the changed amount of change. The portable terminal 1 transmits a corrected sound volume change characteristic based on the set sound volume curve to the earphones 2.

The earphones 2 receive the sound signal and the corrected sound volume change characteristic transmitted from the portable terminal 1. The earphones 2 emit a sound based on the received sound signal at sound volume based on the corrected sound volume change characteristic.

Note that the portable terminal 1, for example, downloads a dedicated application program for setting the corrected sound volume change characteristic from a server in advance. The portable terminal 1 uses the dedicated application program to allow the user to readily make fine sound volume adjustment in a preferred sound volume region.

The configuration of the portable terminal 1 will be described in detail. The portable terminal 1 includes the display 11, a flash memory 12, a RAM 13, a network interface (network I/F) 14, a CPU 15, a touch panel 16, and a short-range communication I/F 17, as shown in FIG. 3. The touch panel 16 described in this example is an example of a user interface in the present disclosure. The short-range communication I/F 17 described in this example is an example of a transmitter in the present disclosure.

The CPU 15 reads a predetermined program stored in the flash memory 12 into the RAM 13 to perform various operations. Note that the program does not need to be stored in the flash memory 12 of the apparatus including the CPU 15. The CPU 15 may download a program whenever necessary from another apparatus such as a server (not shown) and load the program into the RAM 13.

The CPU 15 further includes a correction instruction acceptor 150 and a change characteristic generator 151 as functional portions. The CPU 15 reads a program relating to correction instruction acceptance and change characteristic generation from the flash memory 12 into the RAM 13. The CPU 15 thus forms the correction instruction acceptor 150 and the change characteristic generator 151. The change characteristic generator 151 will be described later.

The display 11 displays the Display dBA button 31, a sound volume displaying text 32, the GO button 33, a sound volume curve displaying image 34, and a Reset button 35, as shown in FIGS. 4, 5 and 6. The screen shown in FIG. 4 is displayed when the dedicated application program for setting the corrected sound volume change characteristic is executed. The display 11 displays the Display dBA button 31 as an initial screen, as shown in FIG. 4.

The touch panel 16 is layered on the display 11. In other words, the touch panel 16 and the display 11 form a graphical user interface (GUI). The touch panel 16 accepts, for example, a tapping or sliding operation performed by the user on the operation surface. In this example, the touch panel 16 is an electrostatic-capacitive touch panel that detects a change in electrostatic capacitance caused when the user touches the operation surface to determine whether or not an operation has been performed and the position where the user has performed the touching operation.

The touch panel 16 accepts a tapping operation performed by the user via the Display dBA button 31 displayed on the display 11. When the user taps the Display dBA button 31, the display 11 displays the current sound volume in the sound volume displaying text 32, as shown in FIG. 5. The display 11 further displays the GO button 33.

The touch panel 16 further accepts a tapping operation (correction instruction operation) performed by the user via the GO button 33. When the user taps the GO button 33 displayed on the display 11, the touch panel 16 accepts a correction instruction of correcting the sound volume change characteristic corresponding to the current sound volume. The tapping operation performed by the user on the GO button 33 will be hereinafter referred to as a correction instruction operation.

When the display 11 accepts the tapping operation performed by the user on the GO button 33, the display 11 displays a sound volume curve in the sound volume curve displaying image 34, as shown in FIG. 6. In this case, the display 11 displays the current sound volume, the minimum sound volume after the change, and the maximum sound volume after the change in the sound volume curve displaying image 34. The display 11 further displays VOL values corresponding to the current sound volume, the minimum sound volume after the change, and the maximum sound volume after the change in the sound volume curve displaying image 34. The display 11 further displays the Reset button 35 when the display 11 accepts the tapping operation performed by the user on the GO button 33.

The touch panel 16 further accepts a tapping operation performed by the user via the Reset button 35. The display 11 displays the Reset button 35 when the sound volume curve is displayed. When the display 11 accepts a tapping operation performed on the Reset button 35, the display 11 displays only the Display dBA button 31, as shown in FIG. 4.

The short-range communication I/F 17 transmits the sound signal, the corrected sound volume change characteristic, and information on the sound volume adjustment to the earphones 2.

The correction instruction acceptor 150 and the change characteristic generator 151 of the CPU 15 will be described (see FIG. 3). When the correction instruction acceptor 150 accepts the correction instruction operation (tapping operation on GO button 33), the correction instruction acceptor 150 accepts a correction instruction of correcting the sound volume change characteristic in accordance with the sound volume change operation. The change characteristic generator 151 sets a sound volume at the time of acceptance of the correction instruction as a reference value, and generates a corrected sound volume change characteristic by correcting the sound volume change characteristic based on the reference value.

When the change characteristic generator 151 accepts the correction instruction, the change characteristic generator 151 sets the current sound volume as the reference value. When the change characteristic generator 151 accepts the correction instruction, the change characteristic generator 151 generates a corrected sound volume change characteristic by correcting the amount of change per VOL to 2 dBA.

For example, assuming that a user who desires to listen to sounds at small sound volume (quiet sounds) is currently listening to music at a sound volume of 46 dBA. In this case, the current sound volume is the sound volume corresponding to VOL5 (sound volume x10) in the first sound volume curve c1, as shown in FIG. 7. When the change characteristic generator 151 accepts the user's correction instruction operation, the change characteristic generator 151 associates the current sound volume (sound volume x10=46 dBA) with VOL9. The change characteristic generator 151 further generates a corrected sound volume change characteristic by correcting the amount of change per VOL to 2 dBA based on the reference value (sound volume x10=46 dBA) associated with VOL9. In this case, the change characteristic generator 151 generates a corrected sound volume change characteristic based on the second sound volume curve c2 based on the sound volume x10=46 dBA. In other words, the change characteristic generator 151 sets sound volume corresponding to each of the 16 steps from VOL1 to VOL16 between the minimum adjusted sound volume x11 and the maximum adjusted sound volume x12 on the based on the second sound volume curve c2.

Further, assuming, for example, that a user who desires to listen to sounds at great sound volume is currently listening to music at a sound volume of 73 dBA. In this case, the current sound volume is the sound volume corresponding to VOL12 (sound volume x20=73 dBA) in the first sound volume curve c1, as shown in FIG. 7. When the change characteristic generator 151 accepts the user's correction instruction operation, the change characteristic generator 151 associates the current sound volume (sound volume x20=73 dBA) with VOL9. The change characteristic generator 151 generates a corrected sound volume change characteristic by correcting the amount of change per VOL to 2 dBA based on the reference value (sound volume x20=73 dBA) associated with VOL9. In this case, the change characteristic generator 151 generates a corrected sound volume change characteristic based on the third sound volume curve c3 based on the sound volume x20. In other words, the change characteristic generator 151 sets sound volume corresponding to each of the 16 steps from VOL1 to VOL16 between the minimum adjusted sound volume x21 and the maximum adjusted sound volume x22 based on the third sound volume curve c3.

The change characteristic generator 151 calculates the sound volume corresponding to each of VOL1 to VOL16. The calculated sound volume corresponding to each of VOL1 to VOL16 is stored, for example, in the flash memory 12. In this example, the corrected sound volume change characteristic includes step values of VOL1 to VOL16 and the sound volume corresponding to each of VOL1 to VOL16.

In this example, the variation characteristic generator 151 calculates the sound volume corresponding to each of VOL1 to VOL16 based on the expression below (see FIG. 7). Note that z1 in the expression is the amount of change (2 dBA/VOL in this example). It is assumed that the application program screen shown in FIG. 4 is displayed on the display 11. In the expression below, n of VOLn is any value from 1 to 16. The sound volume x0 is the current sound volume.

$$Sound volume corresponding to VOLn = sound volume x 0 - z 1 \times ( 9 - n ) ( for n = 1 to 8 ) \qquad [ Expression 1 ]$$

$$Sound volume corresponding to VOLn = sound volume x 0 + z 1 \times ( n - 9 ) ( for n = 10 to 16 ) \qquad [ Expression 2 ]$$

The portable terminal 1 may use Expression 1 to calculate, for example, the sound volume corresponding to VOL1 (minimum adjusted sound volume x11, x21). The sound volume corresponding to VOL1 in the second sound volume curve c2 is 30 dBA (sound volume x0=46 dBA, z1=2 dBA, n=1). The sound volume corresponding to VOL1 in the third sound volume curve c3 is 57 dBA (sound volume x0=73 dBA, z1=2 dBA, n=1). The portable terminal 1 may use Expression 2 to calculate the sound volume corresponding to VOL16 (maximum adjusted sound volume x12, x22). The sound volume corresponding to VOL16 in the second sound volume curve c2 is 60 dBA (sound volume x0=46 dBA, z1=2 dBA, n=16). The sound volume corresponding to VOL16 in the third sound volume curve c3 is 87 dBA (sound volume x0=73 dBA, z1=2 dBA, n=16).

The change characteristic generator 151 thus may use Expression 1 to calculate the sound volume corresponding to each of VOL1 to VOL8. The change characteristic generator 151 may further use Expression 2 to calculate the sound volume corresponding to VOL10 to VOL16.

In the second sound volume curve c2, the calculated sound volume corresponding to each of VOL1 to VOL8 and VOL10 to VOL16 is stored in the flash memory 12 in association with the VOL (step number), as shown, for example, in FIG. 8.

The operation of the portable terminal 1 will next be described with reference to the flowchart in FIG. 9. Note that this example will be described with reference to a case where the second sound volume curve c2 is generated. In this example, the current sound volume is assumed to be 46 dBA.

When the portable terminal 1 accepts the sound volume change characteristic correction instruction operation according to the sound volume adjustment operation via the touch panel 16 (Yes in S11), the portable terminal 1 obtains the current sound volume (46 dBA, for example) (S12). The portable terminal 1 sets the obtained current sound volume as the reference value (S13) (see FIG. 5). The portable terminal 1 uses Expressions 1 or 2 described above to calculate the sound volume corresponding to each VOL (each of VOL1 to VOL8 and VOL10 to VOL16) (S14). The portable terminal 1 transmits the calculated corrected sound volume change characteristic to the earphones 2 via the short-range communication I/F 17 (S15). The portable terminal 1 updates the displayed sound volume curve in the sound volume curve displaying image 34 displayed on the display 11 based on the calculated corrected sound volume characteristic (S16).

The portable terminal 1 accepts a sound volume adjustment instruction relating to the sound volume adjustment through the user's operation. More specifically, when the portable terminal 1 accepts a sound volume adjustment operation from the user, the portable terminal 1 transmits a sound volume operation value (VOLn) according to the accepted operation to the earphones 2 via the short-range communication I/F 17.

As described above, when the portable terminal 1 accepts the user's correction instruction operation, the portable terminal 1 calculates the sound volume corresponding to each VOL by using the current sound volume as the reference value (sound volume x10 or sound volume x20, for example). The portable terminal 1 transmits the corrected sound volume change characteristic to the earphones 2. Furthermore, the portable terminal 1 accepts an operation of changing VOLn from the user.

Note that when the user taps the Reset button 35, the CPU 15 changes, for example, the second sound volume curve c2 or the third sound volume curve c3 back to the first sound volume curve c1 before the correction. That is, when the user taps the Reset button 35, the CPU 15 adjusts the sound volume based on the first sound volume curve c1. In this case, the CPU 15 does not change the sound volume set by the user.

The display 11 may display the Reset button 35 on the initial screen.

The touch panel 16 may accept the user's operation performed on the GO button 33 even when the sound volume curve displaying image 34 is displaying a sound volume curve. In this case, the CPU 15 updates the sound volume curve before the GO button 33 is operated to a new sound volume curve based on the current sound volume. The display 11 displays the new sound volume curve based on the current sound volume in the sound volume curve displaying image 34. In this case, the portable terminal 1 transmits a corrected sound volume change characteristic based on the new sound volume curve based on the current sound volume to the earphone 2. The portable terminal 1 can thus efficiently generate a new sound volume curve based on the current sound volume in accordance with any processing and operation even after correcting the sound volume change characteristic in accordance with the sound volume change operation.

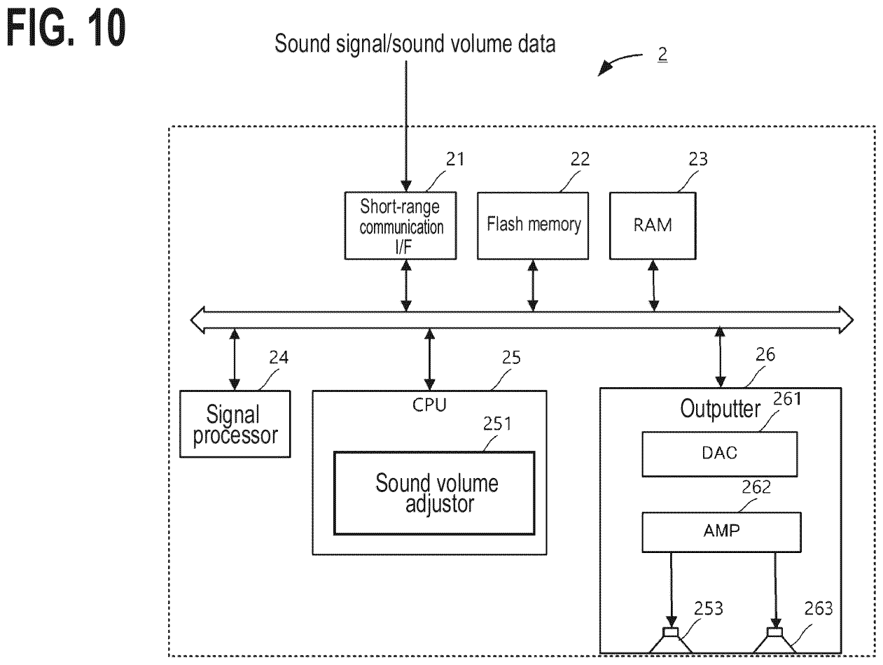

The configuration of the earphones 2 will be described with reference to FIG. 10. FIG. 10 is a block diagram showing an example of the configuration of the earphones 2. The earphones 2 include a short-range communication I/F 21, a flash memory 22, a RAM 23, a signal processor 24, a CPU 25, and an outputter 26.

The short-range communication I/F 21 receives from the portable terminal 1 a sound signal and the corrected sound volume change characteristic selected by the portable terminal 1. The short-range communication I/F 21 further receives sound volume adjustment information relating to the sound volume adjustment from the portable terminal 1. The short-range communication I/F 21 described in this example is an example of a sound single obtainer in the present disclosure.

The CPU 25 harmoniously controls the earphones 2 by reading a predetermined program stored in the flash memory 22 into the RAM 23.

The CPU 25 includes a sound volume adjustor 251. The CPU 25 reads a program relating to the sound volume adjustment from the flash memory 22 into the RAM 23. The CPU 25 thus constitutes the sound volume adjustor 251.

The flash memory 22 stores the corrected sound volume change characteristic received from the portable terminal 1.

When the sound volume adjustor 251 receives the sound volume adjustment information relating to the sound volume adjustment from the portable terminal 1, the sound volume adjustor 251 adjusts the received sound signal so as to have a sound volume according to the sound volume adjustment information. More specifically, when the sound volume adjustor 251 receives the sound volume adjustment information, for example, the sound volume operation value (VOLn), the sound volume adjustor 251 sets a gain value corresponding to the received sound volume operation value (VOLn) based on the corrected sound volume change characteristic stored in the flash memory 22.

The signal processor 24 is configured, for example, with a DSP. The signal processor 24 amplifies or attenuates the level of the sound signal in accordance with the set gain value. The signal processor 24 outputs the sound signal having undergone the signal processing to the outputter 26.

The outputter 26 includes a digital-to-analog converter (hereinafter referred to as DAC) 261, an amplifier (hereinafter referred to as AMP) 262, and loudspeakers 263L and 263R. The DAC 261 converts the received sound signal into an analog signal. The AMP 262 amplifies the analog signal to drive the loudspeakers 263L and 263R. The loudspeakers 263L and 263R emit sounds based on the sound signal output from the AMP 262.

The portable terminal 1 thus accepts the user's sound volume adjustment operation, and transmits the sound volume adjustment information relating to the sound volume according to the accepted sound volume adjustment operation to the earphones 2. The earphones 2 amplify or attenuate the level of the sound signal based on the received sound volume adjustment information. The sound volume setting system 100 in this example can thus perform fine sound volume adjustment at sound volume frequently used by the user.

This example has been described with reference to the case where the difference between the minimum adjusted sound volume and the maximum adjusted sound volume is corrected to 30 dBA, which is smaller than the difference before the correction, but the present disclosure is not necessarily limited thereto. The portable terminal 1 may correct the corrected sound volume change characteristic in such a way that the difference between the minimum adjusted sound volume and the maximum adjusted sound volume becomes a value greater than the difference (60 dBA) between the minimum sound volume x1 and the maximum sound volume x2 (80 dBA, for example) in the first sound volume curve c1. In this case, the portable terminal 1 also sets the amount of change per VOL to be greater than the amount of change in the first sound volume curve c1. The sound volume setting system 100 thus allows the user to efficiently change the sound volume. That is, the sound volume setting system 100 corrects the sound volume change characteristic based on the sound volume at the time of acceptance of the correction instruction, and can therefore readily correct the sound volume change characteristic in accordance with the sound volume change operation in a sound volume region frequently used by the user.

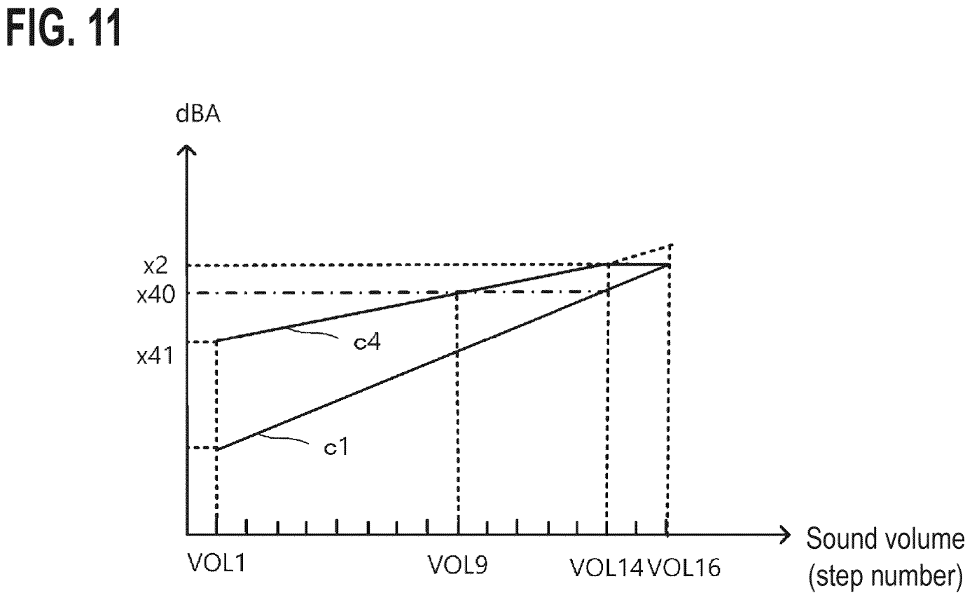

In Variation 1, a case where the user prefers a great sound volume region will be described with reference to FIG. 11. FIG. 11 is a descriptive diagram showing an example of a fourth sound volume curve c4 in Variation 1. In this example, a corrected sound volume change characteristic showing that the sound volume does not exceed the maximum sound volume (upper limit) x2 is generated. That is, the corrected sound volume change characteristic in Variation 1 shows that even when the VOL is increased further above the VOL equal to the maximum sound volume x2, the sound volume does not exceed the maximum sound volume. Variation 1 will be described with reference to the operation of the portable terminal 1.

In this example, the description will be made on the assumption that the maximum sound volume x2 is 90 dBA. In this example, a corrected sound volume change characteristic is so generated that the sound volume is changed by the amount of 2 dBA/VOL based on the current sound volume, as in the first embodiment. Furthermore, in this example, the description will be made on the assumption that the current sound volume is 82 dBA. Note that the sound volume x41 shown in FIG. 11 indicates the minimum adjusted sound volume in the fourth sound volume curve c4.

When the change characteristic generator 151 accepts the correction instruction operation, the change characteristic generator 151 sets the current sound volume (82 dBA, for example) as the reference value. The current sound volume is the sound volume corresponding to VOL14 on the first sound volume curve c1. The change characteristic generator 151 associates the current sound volume (82 dBA, for example) with VOL9. The change characteristic generator 151 generates a corrected sound volume change characteristic by correcting the amount of change per VOL to 2 dBA based on the reference value (x40=82 dBA) associated with VOL9. The variation characteristic generator 151 uses Expression 1 described above to calculate VOL1 to VOL8. The variation characteristic generator 151 uses Expression 2 described above to calculate VOL10 to VOL16. In this case, the amount of change is 2 dBA/VOL. When the sound volume corresponding to VOLn (n=1 to 16) exceeds 90 dBA, the change characteristic generator 151 sets the sound volume to 90 dBA.

In the fourth sound volume curve c4, the sound volume corresponding to VOL14 is 90 dBA, as shown in FIG. 11. The change characteristic generator 151 sets the sound volume corresponding to each of VOL15 and VOL16 to the maximum sound volume x2 (90 dBA) so that the sound volume corresponding to each of VOL14 to VOL16 does not exceed the maximum sound volume x2.

The portable terminal 1 in Variation 1 thus sets the maximum sound volume x2 in advance so that the sound volume corresponding to each of VOL1 to VOL16 after the correction does not exceed the maximum sound volume. The portable terminal 1 in Variation 1 therefore does not output a sound signal that exceeds the reproduction capacity of the loudspeakers 263L and 263R, and can therefore suppress deterioration of sound quality. The portable terminal 1 in Variation 1 can further suppress discomfort caused by great sound volume.

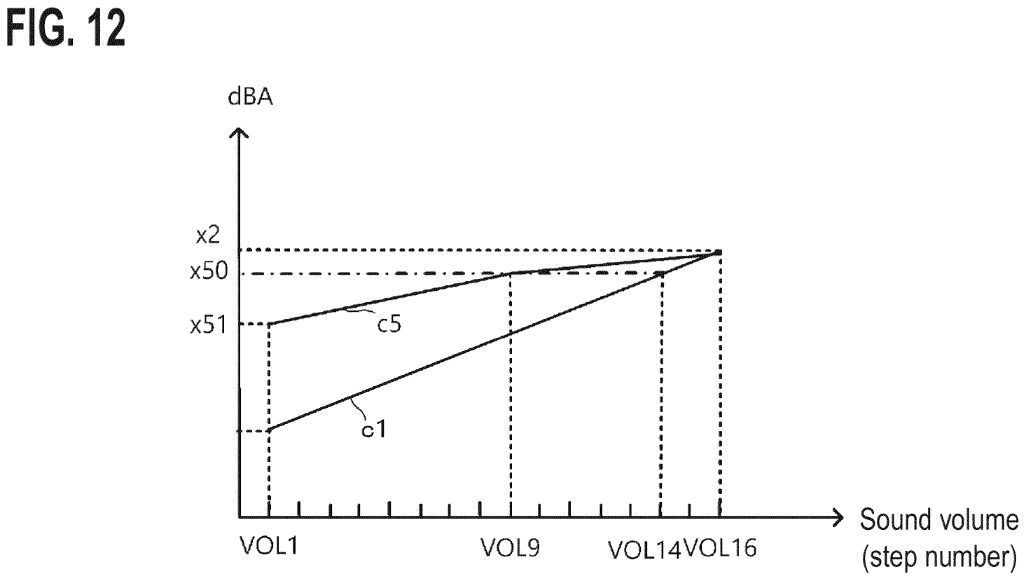

In Variation 2, a case where the user prefers a great sound volume region different from that in Variation 1 will be described with reference to FIG. 12. FIG. 12 is a descriptive diagram showing an example of a fifth sound volume curve c5 in Variation 2. In this example, a corrected sound volume change characteristic showing that the sound volume does not exceed the maximum sound volume x2 (90 dBA, for example) is generated, as in Variation 1. In Variation 2, however, the corrected sound volume change characteristic is so generated that the amount of change between the sound volumes from VOL1 to VOL9 differs from the amount of change between the sound volumes from VOL9 to VOL16. In this example, the description will be made on the assumption that the amount of change between the sound volumes from VOL1 to VOL9 is 2 dBA/VOL, as in the first embodiment. Variation 2 will be described with reference to the operation of the portable terminal 1. Furthermore, in this example, the description will be made on the assumption that the current sound volume is 82 dBA.

The current sound volume is the sound volume corresponding to VOL14 in the first sound volume curve c1. When the change characteristic generator 151 accepts the correction instruction operation, the change characteristic generator 151 sets the current sound volume (82 dBA, for example) as the reference value. In other words, the change characteristic generator 151 associates the current sound volume with VOL9. The change characteristic generator 151 calculates the sound volume corresponding to each of VOL1 to VOL8 by using Expression 1 described above based on the sound volume x50 corresponding to VOL9 (82 dBA in example in FIG. 12) in such a way that the amount of change between the sound volumes from VOL1 to VOL8 is 2 dB/VOL. The variation characteristic generator 151 calculates the amount of change used to calculate the sound volume corresponding to each of VOL10 to VOL16 by using Expression 3 below.

$$Amount of change between the sound volumes from VOL 9 to 16 = ( maximum sound volume x 2 - sound volume x 50 ) \div 7 steps \qquad Expression 3$$

In Expression 3, seven steps represent the number of steps from VOL10 to VOL16. The maximum sound volume x2 is 90 dBA. Furthermore, the sound volume x50 is 82 dBA. That is, when the change characteristic generator 151 calculates the amount of change between the sound volumes from VOL9 to VOL16 by using Expression 3 described above, the amount of change is 1 dBA/VOL (rounded down to nearest whole number). The change characteristic generator 151 calculates the sound volume corresponding to each of VOL10 to VOL16 by using Expression 2 described above. In this case, the change characteristic generator 151 calculates the sound volume by using the calculated amount of change of 1 dBA/VOL.

The change characteristic generator 151 thus generates the corrected sound volume change characteristic based on the fifth sound volume curve c5 shown in FIG. 12. In Variation 2, the amount of change before VOL9 is made different from the amount of change after VOL9. The corrected sound volume change characteristic is generated by calculating the amount of change between the sound volumes from VOL9 to VOL16 based on the maximum sound volume x2, so that the sound volume does not exceed the maximum sound volume x2 even when a large reference value has been set. The portable terminal 1 in Variation 2 can therefore make fine sound volume adjustment in the user's preferred sound volume region but does not output a sound signal that exceeds the reproduction capacity of the loudspeakers 263L and 263R, so that deterioration of sound quality can be suppressed. Furthermore, the portable terminal 1 in Variation 2 can suppress discomfort caused by great sound volume.

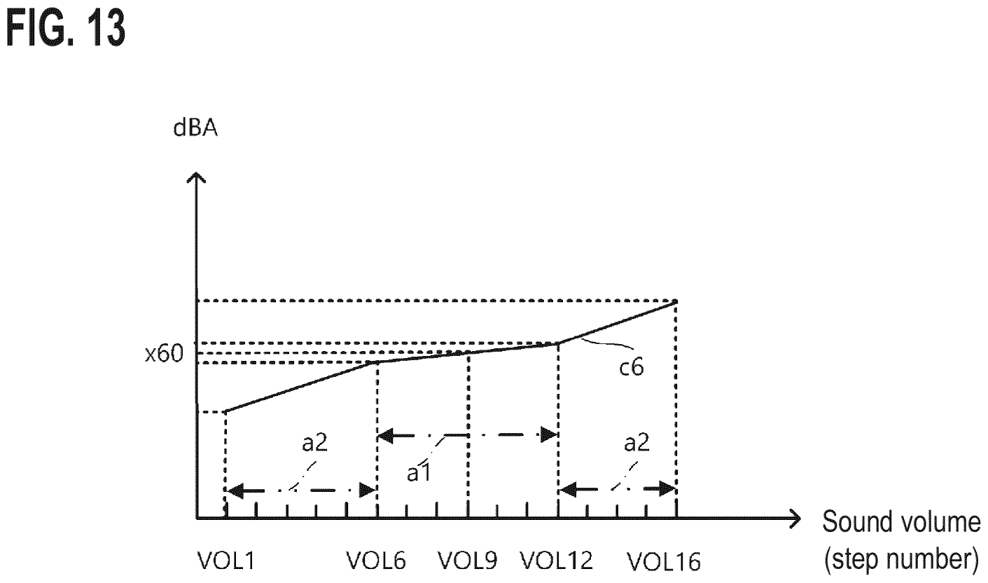

In Variation 3, a case where a corrected sound volume change characteristic is so generated that finer sound volume adjustment can be partially made (from VOL6 to VOL12, for example) will be described with reference to FIG. 13. FIG. 13 is a descriptive diagram showing an example of a sixth sound volume curve c6 in Variation 3. In this example, the amount of change between sound volumes from VOL6 to VOL12 is set to 1 dBA/VOL. The amount of change between sound volumes from VOL1 to VOL6 and from VOL12 to VOL16 is set, for example, to 3 dBA/VOL.

In this example, the sixth sound volume curve c6 will be described with the sixth sound volume curve c6 divided into a region a1 and a region a2, as shown in FIG. 13. The region al indicates the region from VOL6 to VOL12. The region a2 indicates the regions from VOL1 to VOL6 and from VOL12 to VOL16. Variation 3 will be described with reference to the operation of the portable terminal 1.

When the change characteristic generator 151 accepts the correction instruction operation, the change characteristic generator 151 sets the current sound volume x60 as the reference value. In other words, the change characteristic generator 151 associates the current sound volume with VOL9.

The change characteristic generator 151 calculates the sound volume corresponding to each of VOL1 to VOL8 by using Expression 1 described above. In this case, the change characteristic generator 151 calculates the sound volume corresponding to each of VOL1 to VOL6, which belong to the region a2, out of VOL1 to VOL8 by setting the amount of change Z1 to 3 dBA/VOL. The change characteristic generator 151 calculates the sound volume corresponding to each of VOL7 and VOL8, which belong to the region a1, by setting the amount of change Z1 to 1 dBA/VOL.

The change characteristic generator 151 calculates the sound volume corresponding to each of VOL10 to VOL16 by using Expression 2 described above. In this case, the change characteristic generator 151 calculates the sound volume corresponding to each of VOL12 to VOL16, which belong to the region a2, out of VOL10 to VOL16 by setting the amount of change Z1 to 3 dBA/VOL. The change characteristic generator 151 calculates the sound volume corresponding to each of VOL10 and VOL11, which belong to the region a1, by setting the amount of change Z1 to 1 dBA/VOL.

The change characteristic generator 151 thus generates the corrected sound volume change characteristic based on the sixth sound volume curve c6 shown in FIG. 13. In Variation 3, the amount of change in the region a1 is smaller than the amount of change in the region a2. The portable terminal 1 in Variation 3 thus generates a corrected sound volume change characteristic with the amount of change in the region al being smaller than the amount of change in the region a2, so that finer sound volume adjustment can be made in the sound volume region frequently used by the user. Furthermore, the portable terminal 1 provides a sound volume adjustment width wider than that provided by the corrected sound volume change characteristic showing the sound volume corresponding to each of VOL1 to VOL16 that is calculated by using the amount of change of 1 dBA/VOL. The portable terminal 1 can therefore adjust the sound volume over a wider sound volume adjustment width, and can also make finer sound volume adjustment at a sound volume region frequently used by the user.

Note that the region a1 is not limited to VOL6 to VOL12. The region a1 may be larger or smaller than the region shown in FIG. 13. In this case, the region a2 is changed in accordance with the region a1.

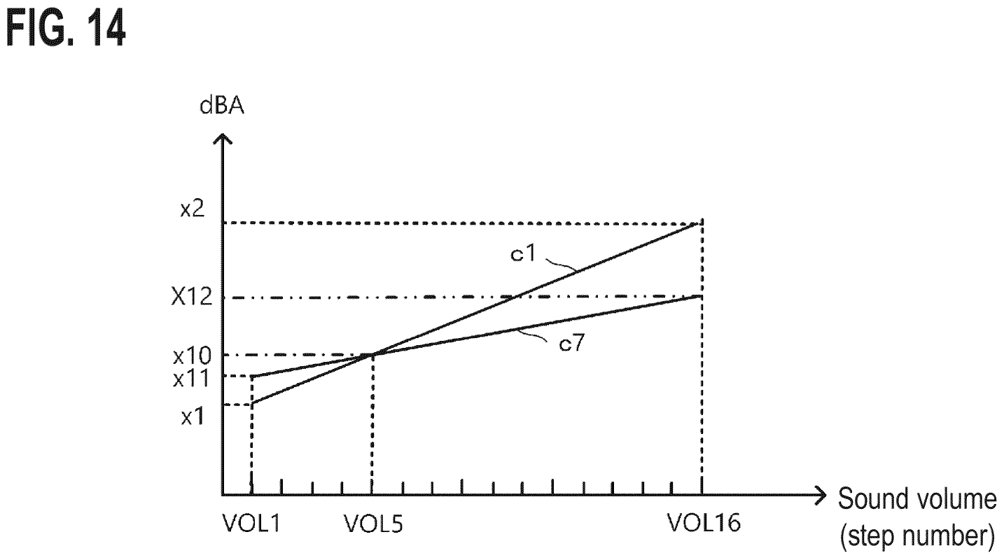

In Variation 4, generation of a corrected sound volume change characteristic in the user's preferred sound volume region will be described with reference to FIG. 14. FIG. 14 is a descriptive diagram showing an example of a seventh sound volume curve c7 in Variation 4. Note that Variation 4 will be described with reference to the operation of the portable terminal 1. Variation 4 will further be described with reference to a case where the current sound volume is the sound volume x10 corresponding to VOL5 in the first sound volume curve c1.

The portable terminal 1 changes the amount of change per VOL from 4 dBA to 2 dBA, as in the first embodiment. When the amount of change is changed, the sound volume adjustment width is also changed.

The portable terminal 1 sets the current sound volume (46 dBA) as the reference value. The current sound volume is the sound volume corresponding to VOL5 in the first sound volume curve c1. The portable terminal 1 in Variation 4 differs from the portable terminal 1 in the first embodiment in that the current sound volume is not associated with VOL9, but is maintained at VOL5. The portable terminal 1 sets the sound volume corresponding to VOL5 as the reference value and generates the seventh sound volume curve c7, as shown in FIG. 14. The portable terminal 1 calculate the sound volumes corresponding to each of VOL1 to VOL4 by using Expression 1 described above. The portable terminal 1 calculates the sound volume corresponding to each of VOL6 to VOL16 by using Expression 2 described above.

In Variation 4, the sound volume corresponding to VOL5 is used as the reference value, so that the sound volume adjustment width from VOL6 to VOL16 is greater than the sound volume adjustment width from VOL1 to VOL4. That is, the portable terminal 1 allows the user who is increasing the sound volume to adjust the sound volume at greater sound volume than in the first embodiment.

Note in this example that the sound volume corresponding to VOL5 is set as the reference value, but not necessarily. When the current sound volume is the sound volume corresponding to VOL12 in the first sound volume curve c1, the portable terminal 1 may generate a corrected sound volume change characteristic based on the sound volume corresponding to VOL12. In this case, the portable terminal 1 calculates the sound volume corresponding to each of VOL1 to VOL11 by using Expression 1 described above. The portable terminal 1 calculates the sound volume corresponding to each of VOL13 to VOL16 by using Expression 2 described above. The portable terminal 1 thus allows the user who is decreasing the sound volume to adjust the sound volume at smaller sound volume than in the first embodiment.

The description of the present embodiment is presented by way of example on every point, and should not considered as limiting. The scope of the present disclosure is not defined by the embodiment described above but is defined by the claims. Furthermore, it is intended that the scope of the present disclosure encompasses all modifications within the scope of the claims and the meaning and scope equivalent thereto.

Note in this example that the portable terminal 1 is wirelessly connected to the earphones 2, but the portable terminal 1 may be connected by wire to the earphones 2.

The portable terminal 1 may transmit the corrected sound volume change characteristic from the terminal to the earphones 2 via wireless communication by using a protocol different from a protocol used to transmit a sound signal via the wireless communication. For example, the portable terminal 1 may transmit a sound signal to the earphones 2 by using the Bluetooth (registered trademark) protocol, which is a highly secure protocol, and transmit a corrected sound volume change characteristic to the earphones 2 by using the Wi-Fi (registered trademark) protocol, which allows transmission of a large amount of information. The portable terminal 1 can improve convenience by transmitting to the earphones 2 a sound signal and a corrected sound volume change characteristic to be transmitted using a protocol suitable for each of the sound signal and the corrected sound volume change characteristic.

When the current sound volume is small, and the current sound volume is associated with VOL9, the sound volume corresponding to each of VOL1 to VOL8 become smaller than 30 dBA in some cases. In this case, for example, the sound volume setting system 100 may generate a sound volume curve that makes the sound volume corresponding to each of VOL1 to VOL8 smaller than 30 dBA. The sound volume setting system 100 may instead generate a sound volume curve that does not make the sound volume corresponding to each of VOL1 to VOL8 smaller than 30 dBA. In the case of great sound volume as well, when the current sound volume is associated with VOL9, the sound volume corresponding to each of VOL10 to VOL16 become greater than 90 dBA in some cases. The sound volume setting system 100 may generate a sound volume curve that makes the sound volume corresponding to each of VOL10 to VOL16 greater than 90 dBA, or may generate a sound volume curve that does not make the sound volume greater than 90 dBA as in Variations 1 and 2.

The earphones 2 may obtain a sound signal from a device other than the portable terminal 1, for example, a server or a PC. In this case, the earphones 2 are connected to the device other than the portable terminal 1 wirelessly or via wire.

The sound volume setting method according to the embodiment of the present disclosure readily allows correction of the sound volume change characteristic in accordance with the sound volume change operation at sound volume frequently used by a user.

While embodiments of the present disclosure have been described, the embodiments are intended as illustrative only and are not intended to limit the scope of the present disclosure. It will be understood that the present disclosure can be embodied in other forms without departing from the scope of the present disclosure, and that other omissions, substitutions, additions, and/or alterations can be made to the embodiments. Thus, these embodiments and modifications thereof are intended to be encompassed by the scope of the present disclosure. The scope of the present disclosure accordingly is to be defined as set forth in the appended claims.

What is claimed is:

1. A sound volume setting method comprising:
receiving a correction instruction to correct a sound volume change characteristic for a sound volume change operation;
setting a reference value to a sound volume that is used at a time when the correction instruction is received;
generating a corrected sound volume change characteristic by correcting the sound volume change characteristic based on the reference value; and
transmitting the corrected sound volume change characteristic.

2. The sound volume setting method according to claim 1, wherein
the corrected sound volume change characteristic is a characteristic in which a volume change amount for the sound volume change operation is corrected so as to be smaller than a pre-correction volume change amount.

3. The sound volume setting method according to claim 2, wherein
the corrected sound volume change characteristic indicates the volume change amount of 2 dBA for each operation value in the sound volume change operation.

4. The sound volume setting method according to claim 1, wherein
generating the corrected sound volume change characteristic comprises generating the corrected sound volume change characteristic to specify a predetermined upper limit sound volume as an upper limit value of the sound volume change operation.

5. The sound volume setting method according to claim 1, comprising:
transmitting the corrected sound volume change characteristic from a terminal to earphones via wireless communication.

6. The sound volume setting method according to claim 5, comprising:
transmitting the corrected sound volume change characteristic from the terminal to the earphones via the wireless communication using a protocol different from a protocol used to transmit a sound signal via the wireless communication.

7. The sound volume setting method according to claim 1, comprising:
receiving, from a user, an operation corresponding to the correction instruction.

8. A sound volume setting terminal comprising:
a correction instruction acceptor configured to receive a correction instruction to correct a sound volume change characteristic for a sound volume change operation;
a change characteristic generator configured to set a reference value to a sound volume that is used at a time when the correction instruction is received, and to generate a corrected sound volume change characteristic by correcting the sound volume change characteristic based on the reference value; and
a transmitter configured to transmit the corrected sound volume change characteristic to another terminal.

9. The sound volume setting terminal according to claim 8, wherein
the change characteristic generator is configured to decrease a volume change amount for the sound volume change operation.

10. The sound volume setting terminal according to claim 9, wherein
the corrected sound volume change characteristic indicates the volume change amount of 2 dBA for each operation value in the sound volume change operation.

11. The sound volume setting terminal according to claim 8, wherein
the change characteristic generator is configured to generate the corrected sound volume change characteristic by generating the corrected sound volume change characteristic to specify a predetermined upper limit sound volume as an upper limit value of the sound volume change operation.

12. The sound volume setting terminal according to claim 8, wherein
the transmitter is configured to transmit the corrected sound volume change characteristic to earphones via wireless communication.

13. The sound volume setting terminal according to claim 8, comprising:
a user interface configured to accept an operation corresponding to the correction instruction from a user.

14. A sound volume setting system comprising:
the sound volume setting terminal according to claim 8; and
earphones comprising:
a sound signal obtainer configured to obtain a sound signal;
a sound volume adjustor configured to adjust the sound volume of the sound signal; and
an outputter configured to output the sound signal,
the sound volume setting terminal further including a transmitter configured to transmit the corrected sound volume change characteristic to the earphones,
the sound volume adjustor being configured to adjust the sound volume of the sound signal based on the corrected sound volume change characteristic, and
the outputter being configured to output the sound signal at the sound volume based on the corrected sound volume change characteristic.

15. Earphones comprising:
a sound signal obtainer configured to obtain a sound signal;
a storage configured to store a corrected sound volume change characteristic received from a portable terminal;
a sound volume adjustor configured to adjust the sound signal to have an adjusted sound volume based on the corrected sound volume change characteristic; and
an outputter configured to output the sound signal at the adjusted sound volume.

16. The earphones according to claim 15, wherein
a volume change amount in the corrected sound volume change characteristic is smaller than a pre-correction volume change amount.

17. The earphones according to claim 16, wherein
the corrected sound volume change characteristic indicates the volume change amount of 2 dBA for each operation value in a sound volume change operation received by the portable terminal.
